(19) United States
(12) Patent Application Publication
(10) Pub. No.: US 2019/0179721 A1
(43) Pub. Date: Jun. 13, 2019

(54) UTILIZING NON-VOLATILE PHASE CHANGE MEMORY IN OFFLINE STATUS AND ERROR DEBUGGING METHODOLOGIES

(71) Applicant: HEWLETT PACKARD ENTERPRISE DEVELOPMENT LP, Houston, TX (US)

(72) Inventors: Mark Vinod Kapoor, Houston, TX (US); Martin McAlee, Taipei (TW); Hermann Wienchoi, Houston, TX (US)

(21) Appl. No.: 16/066,144

(22) PCT Filed: Jan. 26, 2016
(86) PCT No.: PCT/US2016/014909

§ 371 Date: Jun. 26, 2018

(51) Int. Cl. G06F 11/22; G01R 31/28; G06F 11/14

(52) U.S. Cl. CPC G06F 11/2236; G01R 31/2813; G06F 11/1438; G01R 31/2851; G01R 31/2818

(57) ABSTRACT

Methods and apparatus to store fault data and/or status data associated with an integrated circuit (100) into a memristor system (106) are disclosed. An example method includes determining when a fault corresponding to an integrated circuit (100) has occurred, when first data related to the integrated circuit (100) is updated. An example method further includes storing the first data in a first subset of a plurality of resistive elements. An example method further includes, in response to the detection of the fault, storing second data in a second subset of the plurality of resistive elements, the second data corresponding to an error associated with the fault.

### BACKGROUND

Faulty Printed Circuit Boards (PCBs) populated with various types of electrical components arrive at development labs from various locations for error analysis. When an error occurs on a PCB, the voltage regulator on the PCB outputs a fault associated with the error. The fault may be stored in memory to allow engineers to analyze the faulty circuits or systems on the PCBs, The PCBs arrive from various locations that were operated with various firmware versions and/or system configurations that cannot be identified without powering the PCB. However, powering a PCB with incorrect firmware and/or system configurations can lead to additional damage that prevents diagnosis of the error that originally occurred. Additionally, catastrophic errors may shut down a PCB before the PCB can store the fault associated with the catastrophic error into memory.

### BRIEF DESCRIPTION OF THE DRAWINGS

FIGS. 1A, 1B, 10, and 1D are block diagrams of example memristor system to collect fault data and/or status data corresponding to an example integrated circuit in accordance with the present disclosure.

FIG. 2 is a block diagram of an example memristor controller of FIGS. 1A-1D to control the example memristor system of FIGS. 1A-1D.

FIGS. 3 and 4 are flowcharts representative of machine readable instructions that may be executed by the example memristor controller of FIGS. 1A-1D and 2 to operate the example memristor system of FIGS. 1A-1D.

FIG. 5 is a processor platform to execute the instructions of FIGS. 3 and 4 to implement the example memristor controller of FIGS. 1A-1D and 2.

The figures are not to scale. Wherever possible, the same reference numbers will be used throughout the drawing(s) and accompanying written description to refer to the same or like parts.

### DETAILED DESCRIPTION

Non-volatile phase change memory elements (e.g. memristors) have numerous advantages in electrical designs. Memristors are semiconductive devices that have variable resistance. The resistance of a memristor can be changed and/or read by applying various voltages for various amounts of time. Accordingly, a memristor can be implemented as a memory bit. In such an example, applying a first voltage for a first duration of time changes the resistance of the memristor to a low resistance to act like a closed switch. Additionally, applying a second voltage for a second duration of time changes the resistance of the memristor to a high resistance to act like an open switch. The amount of resistance can be equated to a binary value (e.g., like a bit cell) in memory. Small blocks of memristors are able to store data faster than conventional memory. Additionally, stored values in memristors can be determined by measuring the resistance of the memristors. Accordingly, a user can probe memristors externally with a probe to determine data stored in the memristors (e.g., via an oscilloscope) without actually powering up the memristors and/or a processor associated with the memristors.

Examples disclosed herein utilize the properties of memristors to perform status and/or error logging associated with an integrated circuit (IC). Status logging includes determining the status of a system (e.g., status data) associated with the integrated circuit. The status data may include a firmware being utilized by the system, system configurations, operating temperature, ambient temperature, software status, identifiers associated with the integrated circuit and/or a device in communication with the integrated circuit, etc. Error logging includes determining fault data related to an error associated with the integrated circuit. When an error occurs, a voltage regulator down may output fault data to a programmable logic device, an integrated lights out device, and/or a memristor system. As further described herein, the fault data may be minimal or may be more detailed depending on how the memristor system is attached to the integrated circuit.

Conventional techniques for storing fault data and/or status data include storing the data into an active health negative-and (NAND) memory, Electrically Erasable Programmable Read-Only Memory (EEPROM), and/or Read-Only Memory (ROM). However, such conventional techniques require a large amount of space. Additionally, active health NAND memory, EEPROM, and/or ROM cannot be read externally (e.g., via a probe). Therefore, an engineer needs to power a circuits and/or systems on a PCB associated with the memory to determine the stored data. However, powering the circuits and/or systems PCB with incorrect system configurations and/or firmware may lead to additional damage that prevents diagnosis of the error that originally occurred. Additionally, such conventional techniques are slower than examples disclosed herein. Catastrophic errors cause all and/or some of the components of the PCB and memory to shut down immediately. Thus, such conventional techniques are not fast enough to log (e.g., store) a fault associated with the catastrophic error.

Examples described herein communicatively coupe memristors to an integrated circuit to store fault data and/or status data associated with the integrated circuit. Memristors store data much faster than traditional memory. Thus, a fault associated with a catastrophic error can be detected and shared before a catastrophic error shuts-down the components of the PCB. Additionally, data stored in memristors can be read by determining the resistance of the memristors. Therefore, an engineer can determine system configurations, firmware versions, fault data, etc. corresponding to the PCB by probing the memristors externally with a probe without powering up the components of the PCB. In this manner, an engineer can power the PCB with the correct system configurations, options, riser cards, mated system boards, firmware, etc. to prevent further damage. Additionally, components on a PCB can re-boot with correct system configurations, firmware version, etc. when the components are activated/re-activated.

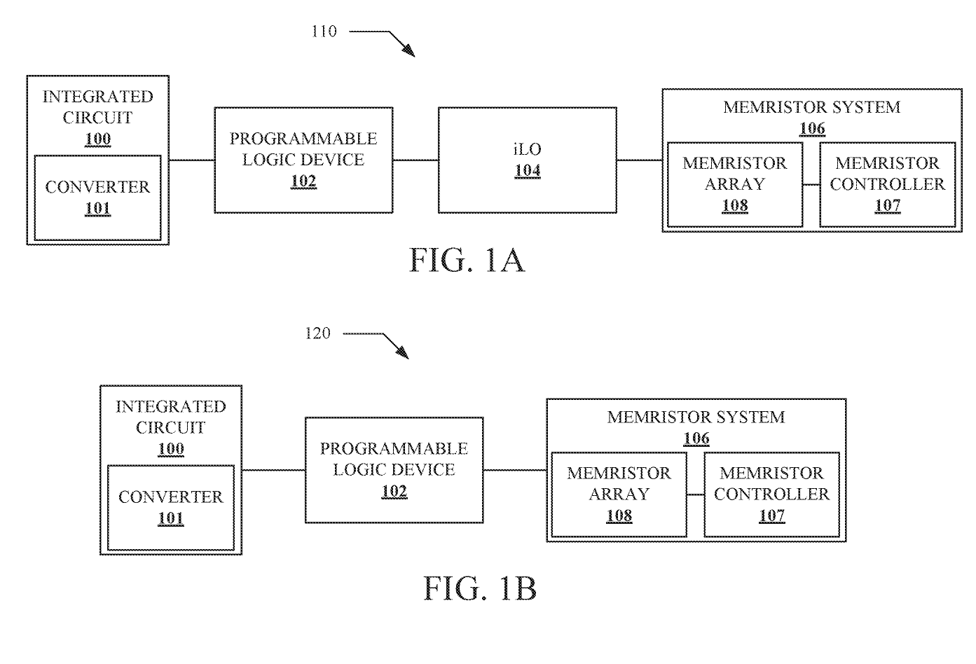

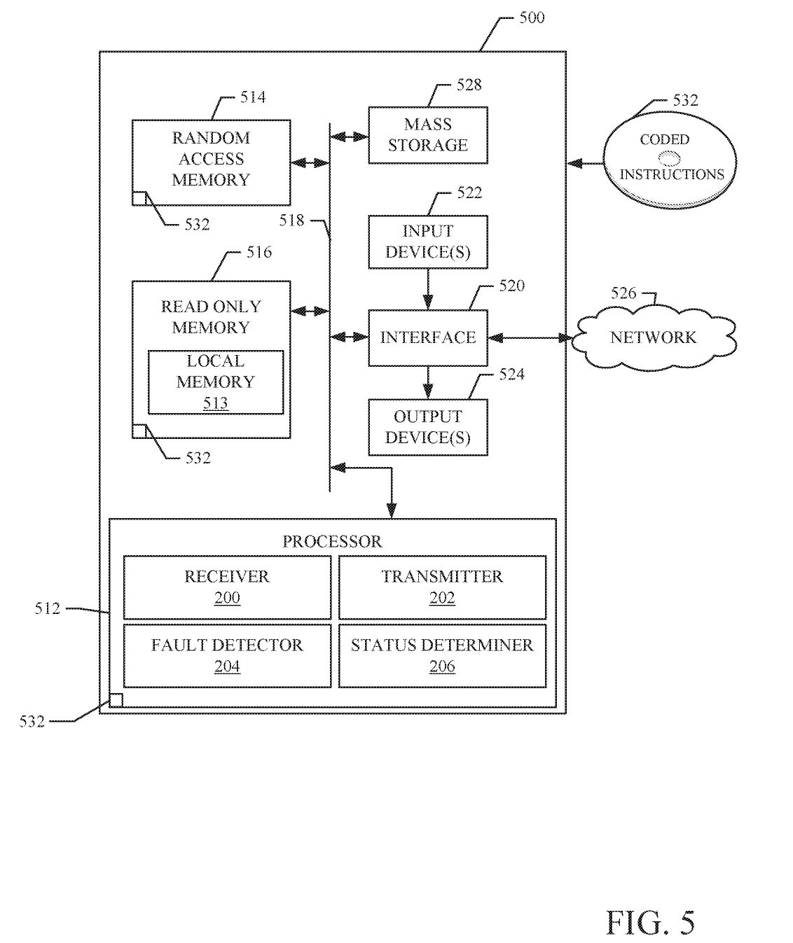

FIGS. 1A, 1B, 10, and 1D are four example block diagrams 110, 120, 130, 140 of different circuit configurations using a memristor system to collect fault data and/or status data. The example block diagrams include an example IC 100, an example converter 101, an example programmable logic device 102, an example Integrated Lights-Out device (iLO) 104, an example memristor system 106, an example memristor controller 107, and an example memristor array 108.

The example IC 100 is semiconductor device including a set of electrical components (e.g., resistors, capacitors, inductors, transistors, etc.). The example IC 100 may be part of a bigger IC and/or in communication with other ICs. For example, the example IC 100 may be part of and/or connected to an Ethernet motherboard, a central processing unit, memory, a server, a processor, a controller, etc. The example integrated circuit 100 includes the example converter 101 to receive a first signal (e.g., first voltage) and output a second signal (e.g. a second voltage). In some examples, the integrated circuit 100 includes and/or is coupled to a processor to output the first signal to the example converter 101 (e.g., when an error occurs and/or to transmit status data). In FIGS. 1A, 1B, 1C, and 1D, the example converter 101 is a voltage regulator. Alternatively, the example converter 101 may be a linear regulator, a multiple-phase regulator, a magnetic converter, an alternating current to direct current (AC-DC) converter (e.g., a rectifier, a mains power supply unit, a switched-mode power supply, etc.), an AC-AC converter (e.g., a transformer, an autotransformer, a voltage converter, a voltage regulator, a cycloconverter, a variable-frequency transformer, etc.), a DC to AC converter (e.g. an inverter), and/or any other device that can convert a first voltage to a second voltage. When the example IC 100 experiences an error, the example converter 101 outputs fault data to an external device (e.g., the programmable logic device 102 and/or the example memristor system 106) via a bus. The bus includes multiple rails to communicate various data to any one of the example programmable logic device 102, the example iLO 104, and/or the example memristor system 106. The fault data output by the example converter 101 is 1 bit or a small number of bits. The fault data output by the example converter 101 is minimal to quickly inform the example programmable logic device 102, the example iLO 104, and/or the example memristor system 106 that the example converter 101 and/or integrated circuit 100 is faulting.

The example programmable logic device 102 receives the minimal fault data from the example converter 101 and outputs the minimal fault data and more detailed fault data. Additionally, once the minimal fault data is received by the example programmable logic device 102, the programmable logic device 102 communicates with the example IC 100 to get additional information about the failure. For example, the additional information may include data related to a type of error that occurred, which part of the IC 100 caused the error, which rail is turning off due to the error, a status of other rails in the bus, and/or whether or not turning off the rail caused the IC 100 to continue operating without a reboot. In some examples, the example programmable logic device 102 includes ambient temperature sensors. In such examples, the example programmable logic device 102 includes the ambient temperature sensed by the sensors in the more detailed fault data, In some examples, the example programmable logic device 102 is a complex programmable logic device (CPLD) including logic implementing disjunctive normal form expressions and/or more specialized logic operations, Alternatively, the example programmable logic device 102 may be a programmable logic array, a programmable array logic device, a generic array logic device, a field-programmable gate array, and/or any other type of programmable logic device. The example programmable logic device 102 outputs the more detailed fault data to the example iLO 104 and/or the example memristor system 106.

The example iLO 104 is a remote server management processor to control and/or monitor status of the example integrated circuit 100 from a remote location. The example iLO 104 timestamps the error when the more detailed fault data is received, In some examples, the example iLO 104 communicates with a basic input/output system (BIOS) and/or unified extensible firmware interface (UEFI) associated with the example IC 100, Communicating with the BIOS and the UEFI allows the example iLO 104 to determine various status data such as system status (e.g., booting, running, idle), a current checkpoint state of the BIOS, stress load of the system, etc. In some examples, the iLO 104 includes a network connection and/or Internet Protocol (IP) address to connect to other management networks. In some examples, the iLO 104 includes a remote web-based console to communicate with the example integrated circuit 100 remotely. Using the remote web-based console, a user can operate features including setup, configuration, remote power on and/or off, secure socket layer security, detailed status (e.g., server status), virtual indicators, and/or diagnostics. In some examples, the iLO 104 outputs a most detailed fault data by outputting the more detailed fault data from the example programmable logic device 102 along with a timestamp, state of the system (e.g., BIOS checkpoints), data related wo whether and/or how long the system was booted up for, the stress load of the system, etc. In some examples, the example programmable logic device 102 and the example iLO 104 may be combined into one device performing the functionalities of both devices.

The example memristor system 106 includes the example memristor controller 107 and the example memristor array 108. In some examples, the memristor system 106 is a separate device (e.g., PCB) attached at least one of the example IC 100, the example programmable logic device 102, and/or the example iLO 104. Alternatively, the example memristor system 106 may be embedded in at least one of the example IC 100, the example programmable logic device 102, and/or the example iLO 104. In FIG. 1A, the example memristor system 106 is attached (e.g., coupled) to the example iLO 104. In FIG. 1B, the memristor system 106 is attached to the example programmable logic device 102. In FIG. 1C, the example memristor system 106 is attached to the example IC 100. In FIG. 1D, the example memristor system 106 is attached to the example IC 100, the example programmable logic device 102, and the example iLO 104. Alternatively, the example FIG. 1D, may include two or more memristor systems 106 (e.g., one attached to the example IC 100, one attached to the example programmable logic device 102, and one attached to the example iLO 104). Alternatively, the example Memristor system 106 may be embedded in any of the example Integrated circuit 100, the example programmable logic device 102, and/or the example iLO 104.

The example memristor controller 107 receives fault data and/or status data from the example converter 101. In some examples, the example memristor controller 107 communicates (e.g., periodically or aperiodically) with the example IC 100, the example programmable logic device 102, and/or the example iLO 104 to determine status data of the example IC 100. The status data may include system configurations, options, riser card identifiers, mated system board identifiers, firmware identifiers, software identifiers, an IC identifier, an operating temperature, an ambient temperature, a timestamp, and/or any other data related to the example IC 100. In some examples, the example memristor controller 107 polls an input associated with the example converter 101 to identify (e.g., detect) a fault output by the example converter 100 associated with the example IC 100. The example memristor controller 107 stores the fault data and/or status data in the example memristor array 108. Additionally, the example memristor controller 107 may read the stored status data from the example memory array 108. For example, if the example IC 100 needs to be rebooted (e.g. restarted), the example memristor controller 107 may read the status data in the example memory array 108 to determine IC system configurations, options, a riser car identifier, a mated system board identifier, and/or firmware version installed on the example IC 100. In such an example, the memristor controller 107 may transmit the system configurations and/or firmware version to the example IC 100 prior to and/or after the reboot. Transmitting the correct firmware various allows the example IC 100 to reboot without causing further damage associated with rebooting with incorrect configurations.

The example memristor array 108 is an array of non-volatile phase change memory elements (e.g. memristors). The example memristor array 108 may include any number of memristors. The memristors in the memristor array 108 are resistive elements created from a thin doped semiconductor film with variable resistance. As voltage is applied to a memristor, the doping of the semiconductor film changes. As the doping changes, the resistance associated with the memristor changes. For example, a memristor may be doped. The doped memristor has a low resistance (e.g., 100 Ohms) and operates like a closed switch. In such an example, the low resistance of the memristor may be associated with a binary value of “1” to indicate “ON.” If a high voltage is applied to the doped memristor for a sufficient duration of time, the dopants drift to cause the memristor to act like undoped semiconductor material. The “undoped” memristor has a high resistance (e.g., 1 megaOhm) and operates like an open switch. In such an example, the high resistance of the memristor may be associated with a binary value of “0” to indicate “ON,” In some examples, the amount of resistance can be associated with an analog value. In such example the example memristor controller 107 outputs a particular voltage for a particular amount of time to change the resistance of a memristor to a particular resistance. The particular resistance can later be read and associated with the stored data (e.g., based on the resistance). As previously described, the resistance is non-volatile. Thus, stored values in memristors can be determined after power is lost and without providing power to any other device. For example, a user can read the stored data by probing the example memristor array 108 without powering the example IC 100 (e.g., via an oscilloscope).

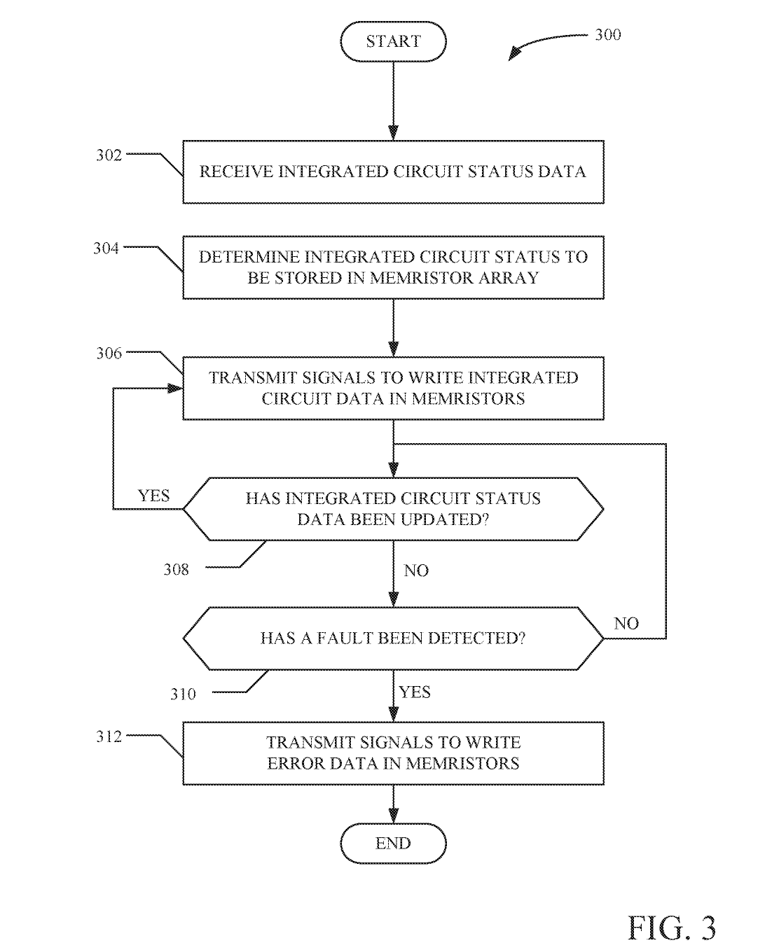

In FIG. 1A, the example memristor system 106 is attached to the example iLO 104. In operation, when an error associated with the example IC 100 and/or the example converter 101 occurs, fault data is transmitted to the example programmable logic device 102 via the example converter 101. The fault data may identify that the error occurred. The example programmable logic device 102 receives the minimal fault data and transmits the minimal fault data to the example iLO 104. Additionally, the example programmable logic device 102 communicates with the example IC 100 to determine additional fault data. As described above, the additional fault data may identify the type of error, the location of the error, a faulty component in the example IC 100, an ambient temperature, and/or any data associated with the error. The example programmable logic device 102 outputs the minimal fault data and the additional data (e.g., the more detailed fault data) to the example iLO 104. The example iLO 104 processes the more detailed fault data. In some examples, the iLO 104 updates the more detailed fault data with a timestamp, system data, a stress load, a state of the system, BIOS checkpoints, etc. to create the most detailed fault data. Additionally, the example iLO 104 transmits status data to the example memristor system 106. The example iLO 104 transmits the most detailed fault data the status data to the example memristor system 106. In some examples, the iLO 104 transmits status updates periodically and/or when the status of the example IC 100 has changed (e.g. updated). In some examples, the example memristor controller 107 communicates the example iLO 104 to request status data associated with the IC 100. The example memristor controller 107 of the example memristor system 106 stores the fault data, the timestamp, and/or the status data in the example memristor array 108. In some examples, the example memristor controller 107 transmits the status data in the memristor array 108 to the example iLO 104, as further described in FIG. 4.

In FIG. 113, the example memristor system 106 is attached directly to the example programmable logic device 102. In operation, when an error associated with the example IC 100 occurs, the minimal fault data is transmitted to the example programmable logic device 102 via the example converter 101. As previously described, the example programmable logic device 102 receives the minimal fault data and communicates with the example integrated circuit 100 to determine additional data. The example programmable logic device 102 combines the minimal fault data with the additional data (e.g., to create more detailed fault data) and transmits the more detailed fault data to the example memristor system 106. Additionally, the example programmable logic device 102 may transmit status data related to the IC 100 to the memristor system 106. The example memristor controller 107 of the example memristor system 106 stores the fault data and/or the status data in the example memristor array 108. In some examples, the example memristor controller 107 transmits the status data in the memristor array 108 to the example programmable logic device 102, as further described in FIG. 4.

In FIG. 1C, the example memristor system 106 is attached directly to the example integrated circuit 100. In operation, when an error associated with the example IC 100 occurs, the minimal fault data is transmitted to the example memristor system 106 via the example converter 101. Additionally, the example IC 100 may transmit status data related to the IC 100 to the memristor system 106. The example memristor controller 107 of the example memristor system 106 stores the fault data and/or the status data in the example memristor array 108. In some examples, the example memristor controller 107 transmits the status data in the memristor array 108 to the example IC 100, as further described in FIG. 4.

In FIG. 1D, the example memristor system 106 is directly attached to the example IC 100, the example programmable logic device 102, and the example iLO 104. Alternatively, any combination of the example IC 100, the example programmable logic device 102, and the example iLO 104 may be connected to the example memristor system 106. In some examples, the example of FIG. 1C may include two or three memristor systems 106, a first memristor system 106 directly attached to the IC 100, a second memristor system 106 directly attached to the example programmable logic device 102, and a third memristor system 106 directly attached to the example iLO 104. The example memristor system 106 of FIG. 10 is attached to the example IC 100. Thus, the example programmable logic device 102, and the example iLO 104, the example memristor controller 107 will receive and store minimal fault data (e.g., from the IC 100), the more detailed fault data (e.g., from the example programmable logic device 102), and the most detailed fault data (e.g. from the iLO 104) into the example memristor array 100. Additionally, status data may be transmitted to the example memristor system 106 periodically, when the status has updated, and/or based on a request from the example memristor controller 107. In some examples, the example memristor controller 107 transmits the status data in the memristor array 108 to the example IC 100, the example programmable logic device 102, and/or the example iLO 104, as further described in FIG. 4.

The example block diagram 110 of FIG. 1A stores status data and the most detailed fault data transmitted by the example iLO 104 in the example memristor array 108. The example block diagram 120 of FIG. 1B stores status data and the more detailed fault data transmitted by the example programmable logic device 102. The example block diagram 130 of FIG. 10 stores status data and the minimal detailed fault data transmitted by the example IC 100 via the example converter 101. As described above, the most detailed fault data from the example iLO 104 contains more detailed fault information than the minimal fault data (e.g., from the example IC 100 in the example block diagram 130 of FIG. C) or the more detailed fault data (e.g., from the example programmable logic device 102 in the example block diagram 120 of FIG. 1B). However, the example block diagram 110 of FIG. 1A takes the most amount of time to receive and store the most detailed fault data, the example block diagram 120 of FIG. 1B takes the second most amount of time to receive and store the more detailed fault data, and the example block diagram 130 of FIG. 10 takes the least amount of time to receive and store the minimal fault data. Accordingly, the example block diagrams 110, 120 may be unable to store fault data associated with a catastrophic error (CATERR). CATERRs are sudden total failures of the example IC 100 where recovery is impossible and the IC 100 immediately shuts down. When a CATERR occurs, all devices (e.g., the example IC 100, the example programmable logic device 102, the example iLO 104, and the example memristor system 106) are shut down. In some examples, a fault associated with the CATERR output by the example converter 101 may not be stored in the example memristor array 108 prior to the shutdown. In such an example, the block diagram 130 of FIG. 1C is able to store the fault associated with the CATERR into the memristor array 108 prior to being shut down. However, the stored fault data (e.g., the minimal fault data) may not include additional data (e.g., operating temperature, a timestamp, etc.) associated with the more detailed fault data and/or the most detailed fault data that would be stored in the example block diagrams 110, 120.

The example block diagram 140 of FIG. 1D is able to receive and store the minimal fault data (e.g., via the example IC 100), the more detailed fault data (e.g., via the example programmable logic device 102), and the most detailed fault data (e.g., via the example iLO 104) at the expense of additional cost, space, and complexity. For example, the example block diagram 140 needs a larger example memristor array 108, additional cabling (e.g., buses), and/or additional memristor systems 106 to store the fault data associated with the example block diagram 140 of FIG. 1D. Additionally, due to space requirements, it may be difficult and/or impossible to implement the example memristor system 106, and thus any one of the other example block diagrams 110, 120, 130 may be used.

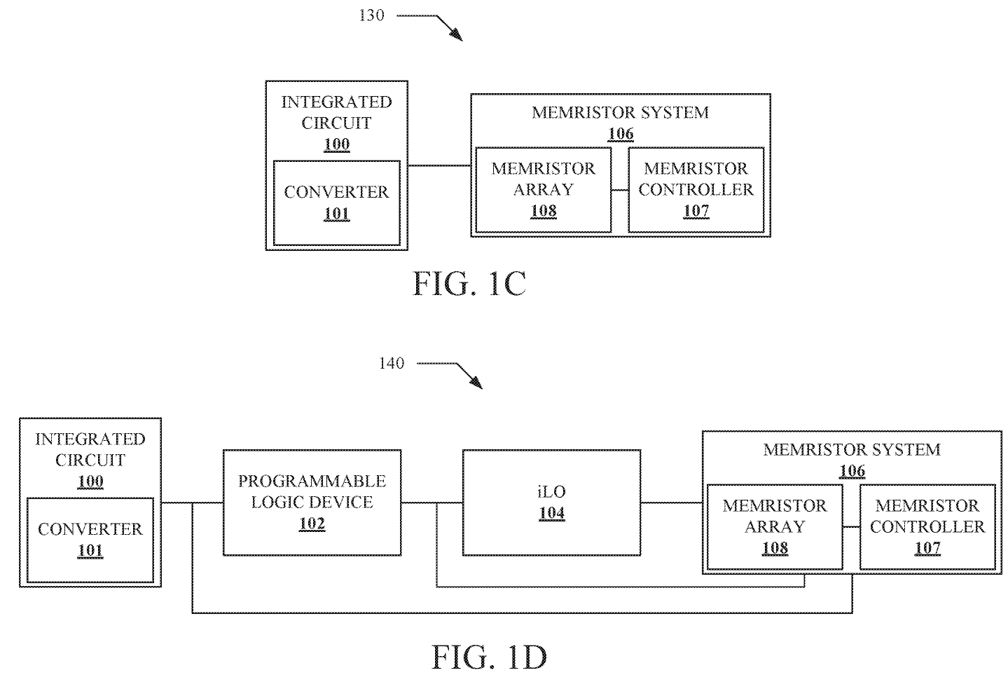

FIG. 2 is a block diagram of the example memristor controller 107 of FIGS. 1A-1D. The example memristor controller 107 includes an example receiver 200, an example transmitter 202, an example fault detector 204, and an example status determiner 206.

The example receiver 200 receives fault data and/or status data from the example IC 100, the example programmable logic device 102, and/or the example iLO 104. In some examples, the example receiver 200 may receive stored data from the example memristor array 108. The example receiver 200 transmits the received data to the example transmitter 202, the example fault detector 204, and/or the example status determiner 206 for further processing.

The example transmitter 202 transmits a write signal or a plurality of write signals to store received fault data and/or status data into the example memory array 108 of FIGS. 1A-1D. The write signal is a voltage signal that is transmitted to particular memristors in the example memristor array 208. As previously described, a memristor can be programmed as ON by applying a first voltage to the memristor or programmed as OFF by applying a second voltage to the memristor. When either the first voltage or the second voltage is applied, the resistance changes to a low resistance or a high resistance which can later be read by applying a third voltage (e.g., a read signal) to the memristor. In some examples, the transmitter 202 transmits signals (e.g., status update signals) with the example IC 100, the example programmable logic device 102, and/or the example iLO 104 of FIGS. 1A and 1D to determine the status of the example IC 100. Additionally, the example transmitter 202 may transmit stored status data from the example IC 100 prior to and/or after a reboot.

The example fault detector 204 processes data received via the example receiver 200 to determine if fault data has been received by the example receiver 200. The example receiver 200 may receive fault data and/or status data. Thus, the example fault detector 204 may sort through received data to determine if the received data is fault data and/or status data. If the example fault detector 204 determines that the received data is associated with an error (e.g., the received data is fault data), the fault detector 204 generates a write signal to store the fault data into the example memristor array 108. If the received data is associated with the IC status, the status determiner 206 processes the received data.

The example status determiner 206 processes received signals to determine how to store the received signals into the example memristor array 206. In some examples, the example status determiner 206 generates a write signal to store the received fault data and/or status data into the example memristor array 208 via the example transmitter 202. In some examples, the example status determiner 206 may analyze the stored status data to generate signal identifying a last known firmware and/or other data based on the stored status data. In such an example, the example transmitter 202 may transmit the generated signal to the example IC 100 (e.g., for a re-boot).

While example manners of implementing the example memristor controller 107 of FIGS. 1A-1D are illustrated in FIG. 2, elements, processes and/or devices illustrated in FIG. 2 may be combined, divided, re-arranged, omitted, eliminated and/or implemented in any other way. Further, the example receiver 200, the example transmitter 202, the example fault detector 204, the example status determiner 206, and/or, more generally, the example memristor controller 107 of FIG. 2, may be implemented by hardware, machine readable instructions, software, firmware and/or any combination of hardware, machine readable instructions, software and/or firmware. Thus, for example, any of the example receiver 200, the example transmitter 202, the example fault detector 204, the example status determiner 206, and/or, more generally, the example distance memristor controller 107 of FIG. 2 could be implemented by analog and/or digital circuit(s), logic circuit(s), programmable processor(s), application specific integrated circuit(s) (ASIC(s)), programmable logic device(s) (PLD(s)) and/or field programmable logic device(s) (FPLD(s)). When reading any of the apparatus or system claims of this patent to cover a purely software and/or firmware implementation, at least one of the example receiver 200, the example transmitter 202, the example fault detector 204, the example status determiner 206, and/or, more generally, the example memristor controller 107 of FIG. 2 is/are hereby expressly defined to include a tangible computer readable storage device or storage disk such as a memory, a digital versatile disk (DVD), a compact disk (CD), a Blu-ray disk, etc. storing the software and/or firmware, Further still, the example memristor controller 107 of FIG. 2 includes elements, processes and/or devices in addition to, or instead of, those illustrated in FIG. 2, and/or may include more than one of any or all of the illustrated elements, processes and devices.

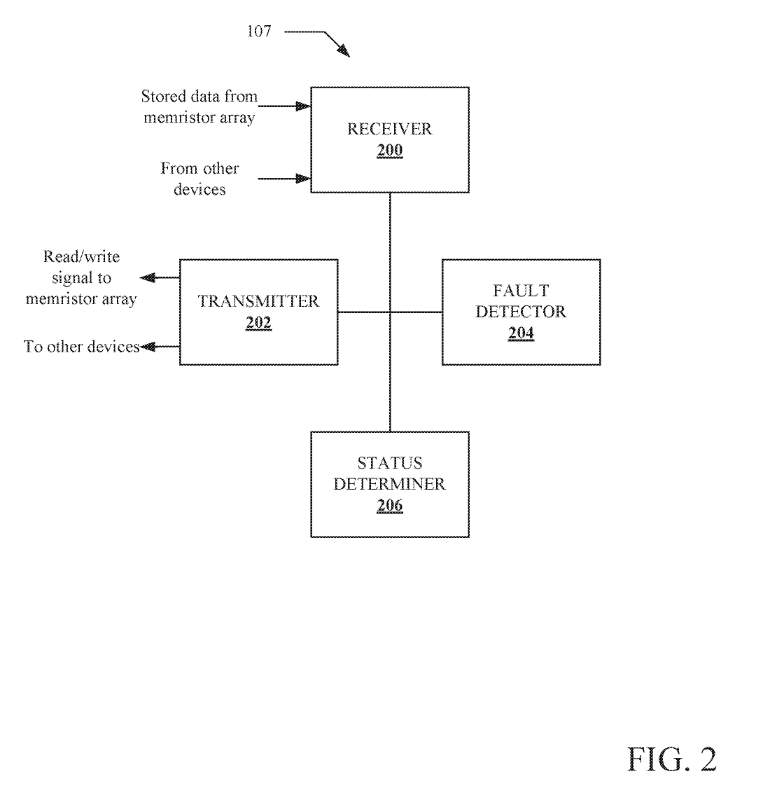

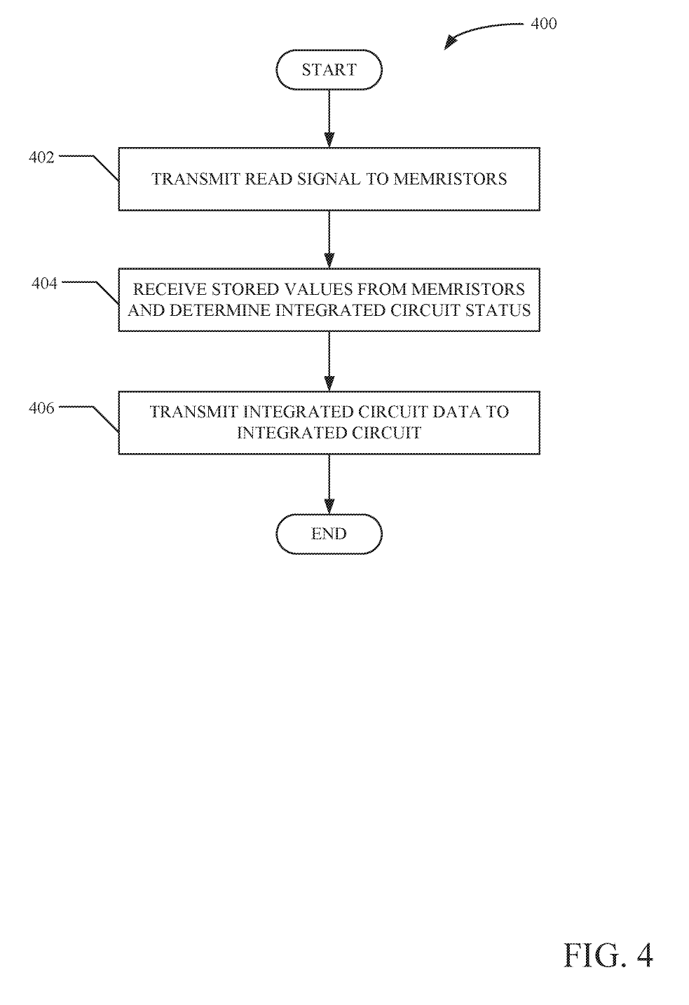

Flowcharts representative of example machine readable instructions for implementing the example memristor controller 107 of FIG. 2 is shown in FIGS. 3 and 4. In the example, the machine readable instructions comprise a program for execution by a processor such as the processor 512 shown in the example processor platform 500 discussed below in connection with FIG. 5. The program may be embodied in machine readable instructions stored on a tangible computer readable storage medium such as a CD-ROM, a floppy disk, a hard drive, a digital versatile disk (DVD), a Blu-ray disk, or a memory associated with the processor 512, but the entire program and/or parts thereof could alternatively be executed by a device other than the processor 512 and/or embodied in firmware or dedicated hardware. Further, although the example programs are described with reference to the flowcharts illustrated in FIGS. 4, many other methods of implementing the example memristor controller 107 of FIG. 2 may alternatively be used. For example, the order of execution of the blocks may be changed, and/or some of the blocks described may be changed, eliminated, or combined.

As mentioned above, the example processes of FIGS. 3 and 4 may be implemented using coded instructions (e.g., computer and/or machine readable instructions) stored on a tangible computer readable storage medium such as a hard disk drive, a flash memory, a read-only memory (ROM), a compact disk (CD), a digital versatile disk (DVD), a cache, a random-access memory (RAM) and/or any other storage device or storage disk in which information is stored for any duration (e.g., for extended time periods, permanently, for brief instances, for temporarily buffering, and/or for caching of the information). As used herein, the term tangible computer readable storage medium is expressly defined to include any type of computer readable storage device and/or storage disk and to exclude propagating signals and to exclude transmission media. As used herein, “tangible computer readable storage medium” and “tangible machine readable storage medium” are used interchangeably. Additionally or alternatively, the example processes of FIGS, 3 and 4 may be implemented using coded instructions (e.g., computer and/or machine readable instructions) stored on a non-transitory computer and/or machine readable medium such as a hard disk drive, a flash memory, a read-only memory, a compact disk, a digital versatile disk, a cache, a random-access memory and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media. As used herein, when the phrase “at least” is used as the transition term in a preamble of a claim, it is open-ended in the same manner as the term “comprising” is open ended.

FIG. 3 is an example flowchart 300 representative of example machine readable instructions that may be executed by the example memristor controller 107 of FIG. 2 to store fault data and/or status data in the example memristor array 108 of FIGS. 1A-1D.

At block 302, the example receiver 200 receives status data associated with the example IC 100 of FIGS. 1A-1D. As previously described, the status data includes system configurations, options, a riser card identifier, a mated system board identifier, a firmware identifier, a software identifier, an IC identifier, an operating temperature, an ambient temperature, a timestamp, and/or any other data related to the example IC 100. At block 304, the example status determiner 206 determines that the received data is status data and generates a write signal to store the received status data into the memristor array 108. The write signal is a voltage and/or series of voltages that, when applied to the example memristor array 108, store the status data into the memristor array 108. At block 306 the example transmitter 202 transmits the write signal to the memristor array 108 to store the status data into the memristor array 108.

At block 308, the status determiner 206 determines if the status data associated with the IC 100 has been updated. In some examples, the status determiner 206 sends requests via the example transmitter 202 to the example IC 100, the example programmable logic device 102, and/or the example iLO 104 to send updated status data. Once the example transmitter 202 receives the updated status data, the example status determiner 206 compares the updated status data with the stored status data to determine if the status data has been updated. In some examples, the IC 100, the example programmable logic device 102, and/or the example iLO 104 may send IC status data only when the example IC 100 has been updated (e.g., based on system configurations, a firmware version, a software version, etc.). In such an example, the status determiner 206 determines that the integrated circuit status data has been updated whenever the example receiver 200 receives additional status data.

If the example status determiner 206 determines that the IC status data has been updated, the example status determiner 206 transmits a write signal via the example transmitter 202 to update the example memristor array 108 based on the updated IC status data. If the example status determiner 206 determines that the IC status data has not been updated, the example fault detector 204 determines if a fault has been detected (block 310). As previously described, the fault detector 204 may determine a fault has been detected when fault data is received by the example receiver 200. If fault data has not been detected, the status determiner 206 continues to determine if the IC status data has been updated. If a fault has been detected, the example fault detector 204 generates a write signal to transmit to the example memristor array 108 via the example transmitter 202 to write the fault data into the example memristor array 108 (block 312). In some examples, if the error associated with the fault does not cause the system to shut down, the process may return to continue to check the IC status data has been updated and/or if additional faults are received by the example receiver 200.

FIG. 4 is an example flowchart 400 representative of example machine readable instructions that may be executed by the example memristor controller 107 of FIG. 2 to read and transmit stored fault data and/or status data in the example memristor array 108 of FIGS. 1A-1D. In some examples, the instructions of the example flowchart 400 are initiated based on power-up/re-boot. In some examples, the instructions of the example flowchart 400 are initiated when the example receiver 200 receives a status request from the example IC 100, the example programmable logic device 102, and/or the example iLO 104.

At block 402, the example transmitter 202 transmits a read signal to the example memristor array 108 to determine values stored in the example memristor array 108. The status determiner 206 receives the values from the example memristor array 108 and determines the stored IC status data based on the received values (block 404). For example, the example status determiner 206 may determine system configuration of the example IC 100, last ran firmware version on the example IC 100, etc. The example status determiner 206 generates a signal to send the example IC 100, the example programmable logic device 102, and/or the example iLO 104 based on the determined status data.

At block 406, the example transmitter202 transmits the status data to the example IC 100, the example programmable logic device 102, and/or the example iLO 104. As previously described, the example IC 100 may initialize (e.g., re-boot) based on the received status data. For example, the IC 100 may initialize with firmware associated with and/or compatible with the firmware identified in the received status data. Additionally or alternatively, the example IC 100 may initialize with system configuration corresponding to the system configurations associated with the status data.

FIG. 5 is a block diagram of an example processor platform 500 capable of executing the instructions of FIGS. 3 and 4 to implement the memristor controller 107 of FIGS. 1A-1D and 2. The processor platform 500 can be, for example, a server, a personal computer, a mobile device (e.g., a cell phone, a smart phone, a tablet such as an iPad™), a personal digital assistant (FDA), an Internet appliance, or any other type of computing device.

The processor platform 500 of the illustrated example includes a processor 512. The processor 512 of the illustrated example is hardware. For example, the processor 512 can be implemented by one or more integrated circuits, logic circuits, microprocessors or controllers from any desired family or manufacturer.

The processor 512 of the illustrated example includes a local memory 513 (e.g., a cache). The processor 512 executes the instructions of FIGS. 3 and 4 to implement the example receiver 200, the example transmitter 202, the example fault detector 204, and the example status determiner 206 to implement the example memristor controller 107. The processor 512 of the illustrated example is in communication with a main memory including a random access memory 514 and a read only memory 516 via a bus 518. The random access memory 514 may be implemented by Synchronous Dynamic Random Access Memory (SDRAM), Dynamic Random Access Memory (DRAM), RAMBUS Dynamic Random Access Memory (RDRAM) and/or any other type of random access memory device. The read only memory 516 may be implemented by flash memory and/or any other desired type of memory device. Access to the main memory 514, 516 is controlled by a memory and/or clock controller.

The processor platform 500 of the illustrated example also includes an interface circuit 520. The interface circuit 520 may be implemented by any type of interface standard, such as an Ethernet interface, a universal serial bus (USB), and/or a PCI express interface.

In the illustrated example, one or more input devices 522 are connected to the interface circuit 520. The input device(s) 522 permit(s) a user to enter data and commands into the processor 512. The input device(s) can be implemented by, for example, an audio sensor, a microphone, a keyboard, a button, a light emitting diode (LED), a mouse, a touchscreen, a track-pad, a trackball, isopoint and/or a voice recognition system.

One or more output devices 524 are also connected to the interface circuit 520 of the illustrated example. The output devices 524 can be implemented, for example, by display devices (e.g., a light emitting diode (LED), an organic light emitting diode (OLED), a liquid crystal display, a cathode ray tube display (CRT), a touchscreen, a tactile output device, a light emitting diode (LED) and/or speakers). The interface circuit 520 of the illustrated example, thus, typically includes a graphics driver card, a graphics driver chip or a graphics driver processor.

The interface circuit 520 of the illustrated example also includes a communication device such as a transmitter, a receiver, a transceiver, a modem and/or network interface card to facilitate exchange of data with external machines (e.g., computing devices of any kind) via a network 526 (e.g., an Ethernet connection, a digital subscriber line (DSL), a telephone line, coaxial cable, a cellular telephone system, etc.).

The processor platform 500 of the illustrated example also includes one or more mass storage devices 528 for storing software and/or data. Examples of such mass storage devices 528 include floppy disk drives, hard drive disks, compact disk drives, Blu-ray disk drives, RAID systems, and digital versatile disk (DVD) drives.

The coded instructions 532 of FIGS. 3 and 4 may be stored in the mass storage device 528, in the random access memory 514, in the read only memory 516, and/or on a removable tangible computer readable storage medium such as a CD or DVD.

From the foregoing, it will be appreciated that the above disclosed method, apparatus, and articles of manufacture utilize a memristor system to store fault data and/or status data associated with an IC. Using example disclosed herein stored fault data and/or status data in the memristor system can be determined (e.g., via a probe) without supplying power to (e.g., powering up) the IC. Additionally, examples disclosed herein can store fault data associated with CATERRs. In some examples, the memristor system is attached directly to the IC to receive faults associated with the CATERRs. In some examples, the memristor system is attached to a programmable device and/or an iLO to receive more detailed fault data. In some examples, the memristor system and/or multiple memristor systems are attached to any combination of the IC, the programmable logic device, and the iLO to receive fault data associated errors that occur within a system. Additionally, the memristor system receives and stores status data associated with the IC. In some examples, the IC 100 uses status data stored in the example memristor system to initialized and/or re-boot the IC 100.

Conventional methods for storing status and/or fault data associated with an IC include storing the status and/or the fault data into active health NAND, EEPROM, and/or ROM attached to the IC. Such conventional methods require more space, cannot be read without powering the IC, and are slower. Conventional methods cannot be read without powering the IC and additional damage can be caused by powering the IC with incorrect (e.g., outdated) configurations and/or firmware. Additionally, the amount of time to store data into such conventional techniques is so long. Thus, conventional techniques are unable to store faults associated with a CATERR (e.g., since CATERRs cause the IC to shut-down). Examples disclosed herein alleviate such problems by utilizing the memristor system to store fault data and/or status data into a faster memristors that can be read without providing power to the IC attached to the memristor system.

Example methods and apparatus are disclosed to store status and/or fault data associated with an integrated circuit. Such an example apparatus includes a plurality of resistive elements, a fault detector to determine when a fault corresponding to an integrated circuit has occurred, and a data determine to, when first data related to the integrated circuit is updated, store the first data in a first subset of the plurality of resistive elements, the data determine to, in response to, in response to the detection of the fault, store second data in a second subset of the plurality of resistive elements, the second data corresponding to an error associated with the fault.

In some examples, the plurality of resistive elements are memristors. In some examples, the first data include an identifier identifying at least one of the integrated circuit, firmware utilized by the integrated circuit, software utilized by to the integrated circuit, hardware corresponding to the integrated circuit, a temperature corresponding to the integrated circuit, or a component associated with the integrated circuit. In some examples, the status determiner is to determine that the integrated circuit has been updated by polling the integrated circuit.

In some examples, the second data includes a timestamp corresponding to when the fault occurred, In some examples the first data and the second data can be read without powering the integrated circuit. In some example the data determine is to, when an error associated with the fault causes the integrated circuit to re-boot, transmit the first data to the integrated circuit prior to the re-booting.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. An apparatus comprising;
a plurality of resistive elements;
a fault detector (204) to determine when a fault corresponding to an integrated circuit (100) has occurred; and
a status determiner (206) to, when first data related to the integrated circuit (100) is updated, store the first data in a first subset of the plurality of resistive elements, the status determiner (206) to, in response to the detection of the fault, store second data in a second subset of the plurality of resistive elements, the second data corresponding to an error associated with the fault.

2. The apparatus of claim 1, wherein the plurality of resistive elements are memristors.

3. The apparatus of claim 1, wherein the first data includes an identifier identifying at least one of the integrated circuit (100), firmware utilized by the integrated circuit (100), software utilized by to the integrated circuit (100), hardware corresponding to the integrated circuit (100), a temperature corresponding to the integrated circuit (100), or a component associated with the integrated circuit (100).

4. The apparatus of claim 1, wherein the status determiner (206) is to determine that the integrated circuit (100) has been updated by polling the integrated circuit (100).

5. The apparatus of claim 1, wherein the second data includes a timestamp corresponding to when the fault occurred.

6. The apparatus of claim 1, wherein the first data and the second data can be read without powering the integrated circuit (100).

7. The apparatus of claim 1, wherein the status determiner (206) is to, when an error associated with the fault causes the integrated circuit (100) to re-boot, transmit the first data to the integrated circuit (100) prior to the re-booting.

8. A method comprising:
determining when a fault corresponding to an integrated circuit (100) has occurred;
when first data related to the integrated circuit (100) is updated, storing the first data in a first subset of a plurality of resistive elements; and
in response to the detection of the fault, storing second data in a second subset of the plurality of resistive elements, the second data corresponding to an error associated with the fault.

9. The method of claim 8, wherein the plurality of resistive elements are memristors.

10. The method of claim 8, wherein the first data includes an identifier identifying at least one of the integrated circuit (100), firmware utilized by the integrated circuit (100), software utilized by to the integrated circuit (100), hardware corresponding to the integrated circuit (100), a temperature corresponding to the integrated circuit (100), or a component associated with the integrated circuit (100).

11. The method of claim 8, further including polling the integrated circuit (100) to determine when the first data has been updated.

12. The method of claim 8, wherein the second data includes a timestamp corresponding to when the fault occurred.

13. The method of claim 8, wherein the first data and the second data can be read without powering the integrated circuit (100).

14. The method of claim 8, further including, when an error associated with the fault causes the integrated circuit to re-boot, transmitting the first data to the integrated circuit (100) prior to the re-booting.

15. A computer readable medium comprising instructions that, when executed, cause a machine to:
determine when a fault corresponding to an integrated circuit (100) has occurred;
when first data related to the integrated circuit (100) is updated, store the first data in a first subset of a plurality of resistive elements; and
in response to the detection of the fault, store second data in a second subset of the plurality of resistive elements, the second data corresponding to an error associated with the fault,
